(19) United States
(12) Patent Application Publication
(10) Pub. No.: US 2012/0049262 A1
(43) Pub. Date: Mar. 1, 2012

(54) A DRAM CELL STRUCTURE WITH EXTENDED TRENCH AND A MANUFACTURING METHOD THEREOF

(75) Inventors: Xiaolu Huang, Shanghai (CN); Jing Chen, Shanghai (CN); Miao Zhang, Shanghai (CN); Xi Wang, Shanghai (CN)

(73) Assignee: SHANGHAI INSTITUTE OF MICROSYSTEM AND INFORMATION TECHNOLOGY, CHINESE ACADEMY, Shanghai (CN)

(21) Appl. No.: 13/002,320

(22) PCT Filed: Nov. 3, 2010
(86) PCT No.: PCT/CN10/78360

§ 371 Date: Dec. 31, 2010

(30) Foreign Application Priority Data
Aug. 24, 2010 (CN) 201010263965.1

(51) Int. Cl. H01L 29/78; H01L 21/8242; B82Y 99/00

(52) U.S. Cl. 257/304; 438/243; 977/755; 257/E29.255; 257/E21.654

(57) ABSTRACT

A DRAM cell structure with extended trench, the DRAM cell structure comprises: a NMOS transistor and a trench capacitor connected with the source electrode of the NMOS transistor; the trench capacitor comprises: a semiconductor substrate; a multilayer structure as the bottom plate of the trench capacitor, formed over the semiconductor substrate, which is composed of N-type SiGe layers and N-type Si layers arranged alternatively; a trench formed through the multilayer structure deeply into the semiconductor substrate, whose sidewall cross section is serrate-shaped; a dielectric layer formed on the inner face of the trench; a first polycrystalline silicon layer which is filled in the trench as the top plate of the trench capacitor; and a P-type Si layer formed over the multilayer structure. The present invention adopts doping epitaxial growth process to fabricate a multilayer structure composed of N-type SiGe layers and N-type Si layers arranged alternatively as the bottom plate of the trench capacitor. Compared with the traditional buried plate, the fabricating process is simplified. In addition, the present invention adopts selective etching process to form a sidewall having a serrate-shaped cross section. This improved structure increases capacitor plate area and thus even thick dielectric layer will achieve required capacitance.

### CROSS REFERENCE TO RELATED PATENT APPLICATION

This patent application is the US national stage of PCT/CN2010/078360 filed on Nov. 3, 2010, which claims the priority of the Chinese patent application No. 201010263965.1 filed on Aug. 24, 2010, that application is incorporated herein by reference.

### FIELD OF THE INVENTION

The present invention relates to a dynamic random access memory (DRAM) cell structure, and particularly, to a DRAM cell structure with extended trench and a manufacturing method thereof.

### BACKGROUND OF THE INVENTION

At present, a kind of 1T1C structure which includes a transistor coupled with a capacitor is generally adopted as a DRAM cell in the semiconductor industry. The original 1T1C structure makes DRAM memory cell be the electronic component which has the highest density and the lowest unit manufacturing cost. As a result, the 1T1C structure takes an irreplaceable part in the computer access device. With the rapid development of semiconductor technology, new DRAM device having higher density and higher power capacity is developed. However, the major problem in DRAM technology is how to fabricate a capacitor having equivalent capacitance while the area of unit element is keeping shrinking.

FIG. 1 is a cross sectional view of the basic DRAM cell structure with a deep trench capacitor which adopts a three-dimensional pattern and the capacitor is formed by a deep trench being etched blow silicon wafer surface to increase capacitor area making use of longitudinal structure in a limit cell surface. This kind of deep trench capacitor has become one of the mainstream high-density DRAM technologies. In the deep trench capacitor, a heavily doped substrate is adopted as bottom plate, capacity medium is fabricated above side wall of the deep trench, the deep trench is filled with heavily doped polycrystalline silicon as top plate connected with source electrode of the transistor through a strap. In order to obtain a DRAM with higher array density, there are various poly strap processes are adopted. For the DRAM having the memory of 256 Mb or above, a fabrication process called “BuriEd Strap Trench” (BEST) is used to prepare for the strap, as shown in FIG. 2. The fabrication process includes the following steps: a) etching the first polycrystalline silicon layer (Poly I) to the position below potential well of the transistor; b) depositing SiO₂ to form a Collar Oxide layer above the side wall; c) filling the trench with the second polycrystalline silicon layer (Poly II); d) backfilling doped polycrystalline on Poly II and forming a self-aligned connection called buried strap (BS); e) proceeding heat treatment to diffuse the impurities to substrate to connect source electrode of the transistor. In order to reduce transistor impedance, ions are implanted into BS region of trench sidewall which is called BS implant to reduce resistance, wherein the collar oxide layer pushes the capacitor to the position under wafer surface and thus prevent interference between the capacitor in horizontal direction and the transistor. Shallow Trench Isolation (STI) is installed in order to avoid any short circuits between capacitor-top-plate and above passive word line in vertical direction. Because of the buried strap adopted in the process, that is, the strap is pushed to the trench sidewall under silicon wafer surface, the deep trench capacitor obtained could be located below the passive word line leading to reduced distance between two word lines and increased density of DRAM array. The manufacturing process of deep trench capacitor is disclosed in Champion Yi, et al. 2004: Introduction to Deep Trench Capacitor Fabrication of High Density DRAM [J]. Equipment for Electronic Products Manufacturing, 112: 56-63.

However, the manufacturing process of deep trench capacitor presents three major challenges. The first issue is that, the deep trench having high aspect ratio required and the lag effect caused make the capacitor is difficult to be fabricated adopting etching process. The second issue is that bottom plate is fabricated using Buried Plate (BP) process which is more complicated and difficult to process. The third issue is that the risk of electric leakage increases because of thin dielectric layer, thus affecting the yield.

### SUMMARY OF THE INVENTION

A DRAM cell structure with extended trench, the DRAM cell structure comprises: a NMOS transistor and a trench capacitor connected with the source electrode of the NMOS transistor;

wherein the trench capacitor comprises: a semiconductor substrate; a multilayer structure as the bottom plate of the trench capacitor, formed over the semiconductor substrate, which is composed of N-type SiGe layers and N-type Si layers arranged alternatively; a trench formed through the multilayer structure deeply into the semiconductor substrate, whose sidewall cross section is serrate-shaped; a dielectric layer formed on the inner face of the trench; a first polycrystalline silicon layer filled in the trench as the top plate of the trench capacitor; and a P-type Si layer formed over the multilayer structure;

wherein the NMOS transistor fabricated on the P-type Si layer.

Preferably, the sidewall of the trench is sunken in each N-type SiGe layer.

Preferably, the thickness of each N-type SiGe layer is more than 30 nm, the thickness of each N-type Si layer is more than 30 nm and the thickness of the P-type layer is more than 100 nm.

Consistent with embodiments of the present invention, a second polycrystalline silicon layer contact to the first polycrystalline silicon layer is formed in the P-type Si layer of the trench capacitor; a collar oxide layer is fabricated on the sidewall of the second polycrystalline silicon layer; a buried strap which is connected with the source electrode of the NMOS transistor through an ion implanted region is fabricated on the top of one side of the second polycrystalline silicon layer; and a shallow trench isolation structure is fabricated on the top of the other side of the second polycrystalline silicon layer.

A method of manufacturing of a DRAM cell structure with extended trench, the method comprises:

(a) creating a multilayer structure on a semiconductor substrate by forming alternative N-type SiGe layers and N-type Si layers adopting doping and epitaxial growth process and then forming a P-type Si layer on the multilayer structure; (b) forming a oxide covering layer on the P-type Si layer and then forming a nitride covering layer on the oxide covering layer; (c) defining etching window adopting photolithographic and etch process and then proceeding trench etching until the semiconductor substrate is exposed; (d) removing parts of the N-type SiGe layers next to the sidewall of the trench adopting selective etching process in order to form a serrate-shaped sidewall cross section; (e) forming a dielectric layer on the inner face of the trench; (f) filling polycrystalline silicon material in the trench to form a first polycrystalline layer and removing redundant polycrystalline material in the surface adopting chemical mechanical planarization process; (g) fabricating a NMOS transistor on the P-type Si layer and forming an electric connection between the source electrode of the NMOS transistor and the first polycrystalline layer.

Any fabricating process for DRAM cell with trench capacitor in the industrial field could be adopted in the MOS process for fabricating NMOS transistor and the strap process for contacting source electrode of NMOS transistor and the first polycrystalline layer. Consistent with embodiments of the present invention, a process called buried strap trench (BEST) is adopted which comprises steps of: (I) etching the first polycrystalline layer to remove that part of the first polycrystalline located in the P-type Si layer; (II) depositing a SiO₂ film which is then etched to form a collar oxide layer on the side wall, and then implanting polycrystalline material to form a second polycrystalline layer which is connected with the first polycrystalline layer; (III) creating a buried strap on the second polycrystalline and connecting the buried strap with the source electrode of NMOS transistor; (IV) creating an ion implantation region between the buried strap and the source electrode of NMOS transistor to induce transistor impedance.

Specifically, step (c) comprises detailed steps: forming a hard mask layer on the nitride covering layer and then forming a photoresist layer on the hard mask layer; creating etching window of the trench on the photoresist layer adopting photolithographic process; transferring the etching window of the trench defined to the hard mask layer; removing the photoresist layer; proceeding trench etching down to the semiconductor substrate; and removing the hard mask.

Preferably, in step (d), the depth of the part etched by selective etching process of the N-type SiGe layer is smaller than the length of corresponding NMOS transistor channel.

The present invention adopts doping epitaxial growth process to fabricate a multilayer structure composed of N-type SiGe layers and N-type Si layers arranged alternatively as the bottom plate of the trench capacitor. Compared with the traditional buried plate, the present invention has many advantages. First of all, the trench depth is less than traditional deep trench capacitor and fabricating process is thus simplified. The defects for the traditional deep trench capacitor such as high aspect ratio and lag effects are overcome in the present invention. In addition, the DRAM cell in the present invention adopts a multilayer structure composed of alternative SiGe layers and Si layers as the bottom plate of the capacitor, and the fabricating process for the multilayer structure is simplified using epitaxial growth process compared with the fabricating method of the bottom plate of traditional deep capacitor. Moreover, compared with the complicated fabricating process for the thin dielectric layer with low leakage current, the improved structure in the present invention increases capacitor plate area and thus even thick dielectric layer will achieve required capacitance.

### BRIEF DESCRIPTION OF THE DRAWINGS

FIG. 1 is a cross sectional view of the basic DRAM cell structure with a deep trench capacitor in prior art.

FIG. 2 is a cross sectional view of the DRAM cell structure with a deep trench capacitor fabricated by BEST process in prior art.

FIG. 3-8 show the manufacturing steps of a DRAM cell structure with a deep trench capacitor, consistent with the first embodiments of the current disclosure; wherein FIG. 8 is a cross sectional view of the DRAM cell structure with a deep trench capacitor obtained consistent with the first embodiment of the current disclosure.

FIG. 9 is cross sectional view of the DRAM cell structure with a deep trench capacitor obtained consistent with the second embodiment of the current disclosure.

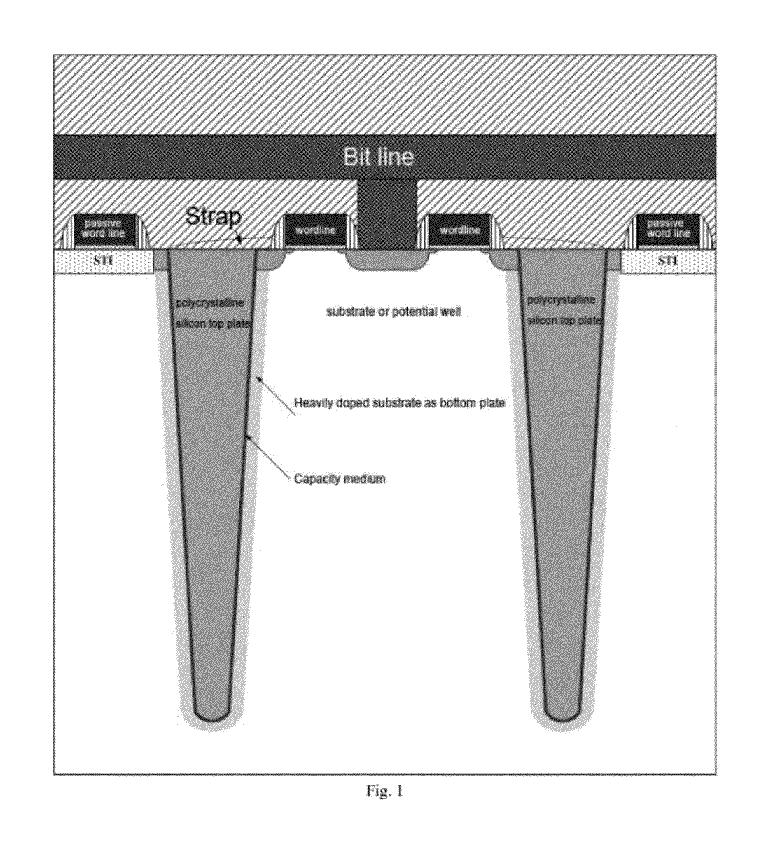

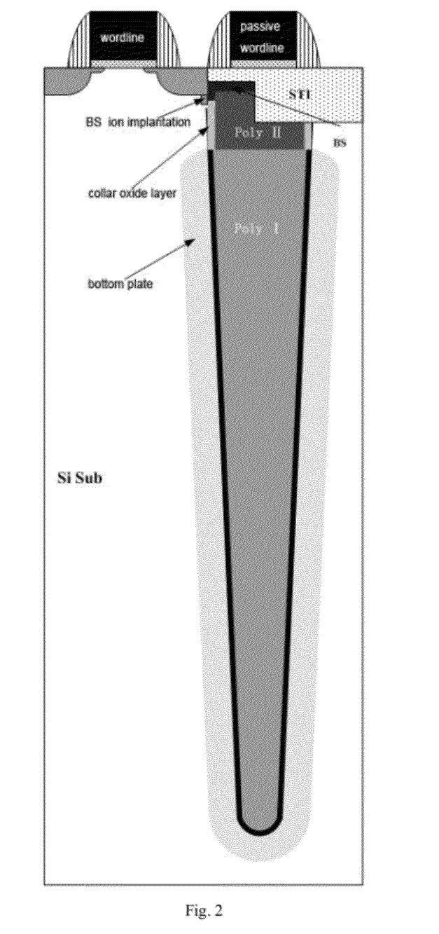

### DETAILED DESCRIPTION OF THE EMBODIMENTS

The present disclosure is further explained in detail according to the accompanying drawings.

### The First Embodiment

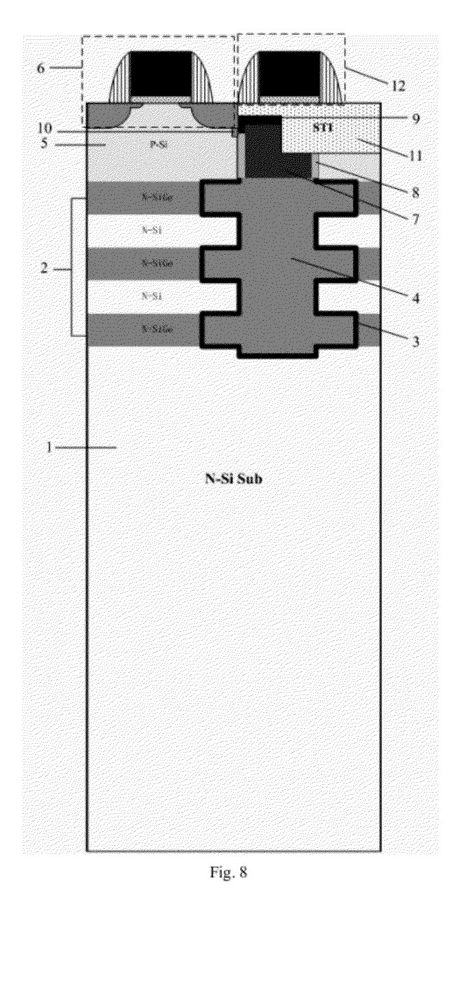

Referring to FIG. 8, a cross sectional view of a DRAM cell structure with extended trench capacitor obtained in this embodiment adopting BEST process to fabricate buried strap, and the DRAM cell structure with extended trench includes: a NMOS transistor 6 and a trench capacitor connected with the source electrode of the NMOS transistor; wherein the trench capacitor includes:

a semiconductor substrate which could be P-type substrate or N-type substrate, a N-type semiconductor substrate 1 is adopted in this embodiment as an example, and the SiGe/Si layers are all N-type;

a multilayer structure 2 as the bottom plate of the trench capacitor, formed on the N-type semiconductor substrate 1, the multilayer structure 2 is composed of N-type SiGe layers and N-type Si layers arranged alternatively; as shown in FIG. 8, a first N-type SiGe layer is formed on the N-type semiconductor substrate 1, a first N-type Si layer is formed on the first N-type SiGe layer, a second N-type SiGe layer is formed on the first N-type Si layer, a second N-type Si layer is formed on the second N-type SiGe layer, and a third N-type SiGe layer is formed on the second N-type Si layer, and so on;

a trench 100 formed through the multilayer structure 2 deeply into the N-type semiconductor substrate 1; the sidewall cross section of the trench 3 is serrate-shaped; that is, the sidewall of the trench 3 is sunken in each N-type SiGe layer, and the sidewall of the trench 3 is protruding in the position of each N-type Si layer compared to the position of each N-type SiGe layer;

a dielectric layer 3 formed on the inner face of the trench 100; the a dielectric layer 4 could be formed of some capacitor dielectric materials, such as ONO dielectric material (0′ means oxide, ‘N’ means nitride) or NO dielectric material (0′ means oxide, ‘N’ means nitride), or other dielectric materials with high dielectric constant;

a first polycrystalline silicon layer 4 which is filled in the trench as the top plate of the trench capacitor;

a P-type Si layer 5 formed on the multilayer structure 2;

a NMOS transistor 6 fabricated on the P-type Si layer 5;

a second polycrystalline silicon layer 7 connected to the first polycrystalline silicon layer 4 is formed in the P-type Si layer 5 of the trench capacitor;

a collar oxide layer 8 fabricated on the sidewall of the second polycrystalline silicon layer 7, the collar oxide layer 8 could be formed of SiO₂ material;

a buried strap 9 fabricated on the top of one side of the second polycrystalline silicon layer 7, the buried strap 9 is connected with the source electrode of the NMOS transistor 6 through an ion implanted region; and

a shallow trench isolation structure 11 fabricated on the top of the other side of the second polycrystalline silicon layer 7 in order to insulate the second polycrystalline silicon layer 7 and prevent any short circuits between the top plate of capacitor (including the first polycrystalline silicon layer 4 and the second polycrystalline silicon layer 7) and above passive word line 12 in vertical direction.

The method of manufacturing of the DRAM cell structure with extended trench includes the following steps:

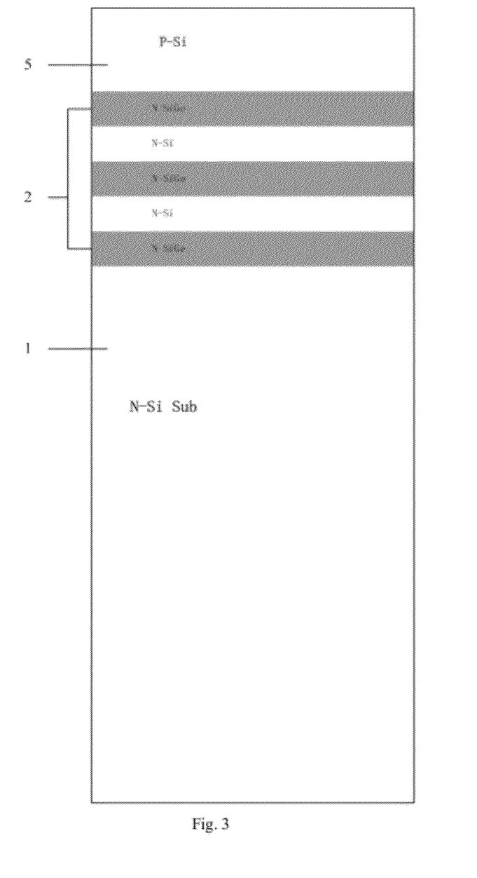

(a) as shown in FIG. 3, form a multilayer structure 2 on a semiconductor substrate 1 by forming alternative N-type SiGe layers and N-type Si layers adopting doping and epitaxial growth process and then form a P-type Si layer 5 with a depth of more than 100 nm on the multilayer structure.

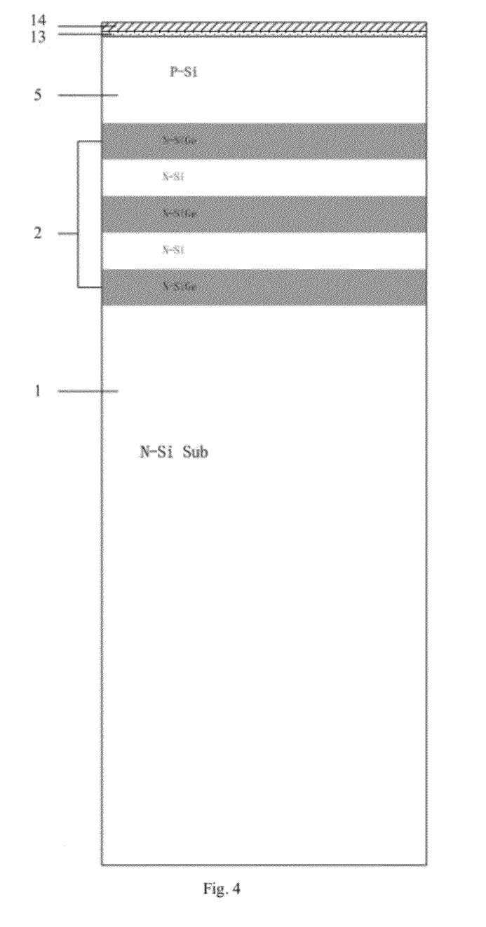

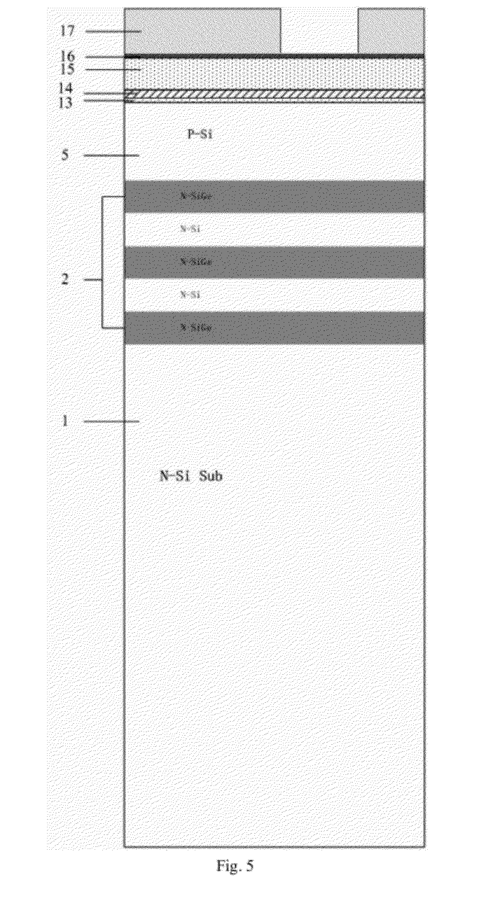

(b) as shown in FIG. 4, form an oxide covering layer 13 on the P-type Si layer, such as a silicon oxide covering layer, adopting thermal oxidation process, and then form a nitride covering layer 14 on the silicon oxide covering layer 13, such as a silicon nitride covering layer, adopting chemical vapor deposition or physical vapor deposition process.

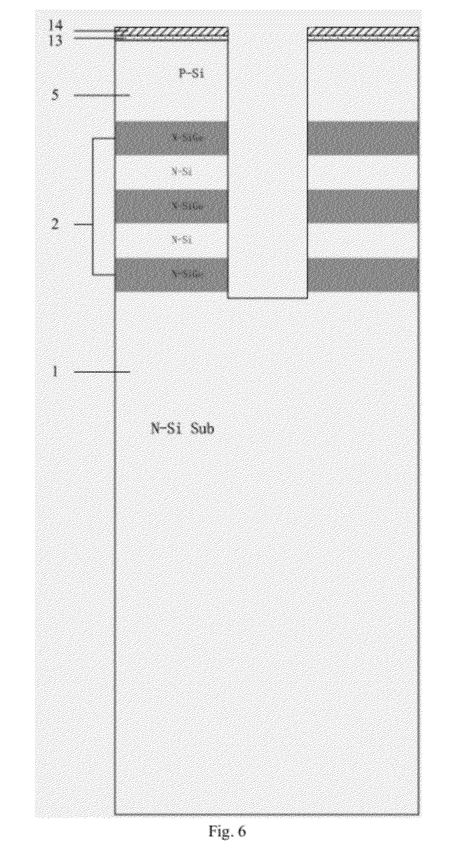

(c) define etching window adopting photolithographic and etch process, for example, form a hard mask layer 15 on the nitride covering layer 14 and then form a photoresist layer 17 on the hard mask layer 15, preferably, the hard mask layer 15 is coated by an anti-reflective coating (ARC) layer 16 and the ARC layer 16 is located between the hard mask 15 and the photoresist layer 17; create etching window of the trench on the photoresist layer 17 adopting photolithographic process; transfer the etching window of the trench defined to the hard mask layer 15; remove the photoresist layer 17 and the ARC layer 16; proceed trench etching down to the semiconductor substrate 1; and remove the hard mask layer 15, as shown in FIG. 6. Besides the photolithographic and etchprocess disclosed in this embodiment, other photoetching process could also be adopted in the present invention.

(d) remove parts of the N-type SiGe layers next to the sidewall of the trench adopting selective etching process in order to form a serrate-shaped sidewall cross section. For example, a sub-atmospheric chemical vapor deposition (SACVD) method is applied with H₂ and HCl gases in a temperature range from 600° C. to 800° C. and at a HCl pressure above 300 Torr.

(e) form a dielectric layer 3 on the inner face of the trench. For example, grow a dielectric layer 3 which is made of ONO dielectric material.

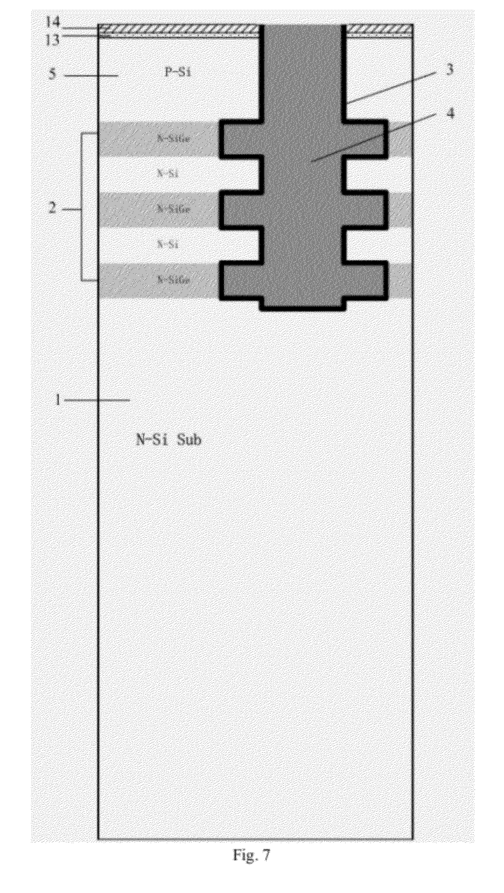

(f) fill polycrystalline silicon material in the trench to form a first polycrystalline layer 4 and remove redundant polycrystalline material in the surface adopting chemical mechanical planarization (CMP) process, as shown in FIG. 7.

(g) remove the oxide covering layer 13 and the nitride covering layer 14, fabricate a NMOS transistor 6 on the P-type Si layer and form an electric connection between the source electrode of the NMOS transistor 6 and the first polycrystalline layer 4. Any MOS technology for manufacturing the NMOS transistor 6 or any strap technology for forming an electric connection between the source electrode of the NMOS transistor 6 and the first polycrystalline layer 4 could adopt any existing deep trench capacitor DRAM cell manufacturing method. In this embodiment, the BEST process is proceeded including following steps: etching the first polycrystalline layer 4 to remove that part of the first polycrystalline located in the P-type Si layer 5; deposite a SiO₂ film which is then etched to form a collar oxide layer 8 on the side wall, and then implant polycrystalline material to form a second polycrystalline layer 7 which is connected with the first polycrystalline layer 4; create a buried strap 9 on the second polycrystalline 7 and then the buried strap 9 is connected with the source electrode of NMOS transistor 6; create an ion implantation region 10 between the buried strap 9 and the source electrode of NMOS transistor 6 to reduce transistor impedance.

In a DRAM array, the grid of NMOS transistor 6 is linked to form a wordline, a passive wordline 12 is located side by side on one side of the wordline. In order to isolate the passive wordline 12, a shallow trench isolation structure 11 is fabricated between the second polycrystalline silicon layer 7 and the passive wordline 12. FIG. 8 is a cross sectional view of the DRAM cell structure with a deep trench capacitor obtained in this embodiment.

The present invention adopts doping epitaxial growth process to fabricate a multilayer structure composed of N-type SiGe layers and N-type Si layers arranged alternatively as the bottom plate of the trench capacitor. Compared with the traditional buried plate, the fabricating process is simplified. In addition, the present invention adopts selective etching process to form a sidewall having a serrate-shaped cross section. This improved structure increases capacitor plate area and thus even thick dielectric layer will achieve required capacitance. Preferably, the thickness of each N-type SiGe layer is more than 30 nm, more preferably, the thickness of each N-type SiGe layer is ranging from 50 nm to 100 nm in this embodiment. Preferably, the thickness of each N-type Si layer is more than 30 nm, more preferably, the thickness of each N-type Si layer is ranging from 50 nm to 100 nm in this embodiment. The number of the N-type SiGe layers and the N-type Si layers and the thickness of each layer should be determined according to the capacitance required. In order to avoid influencing other DRAM cells, the depth of the part etched by selective etching process of the N-type SiGe layer is smaller than the length of corresponding NMOS transistor channel.

### The Second Embodiment

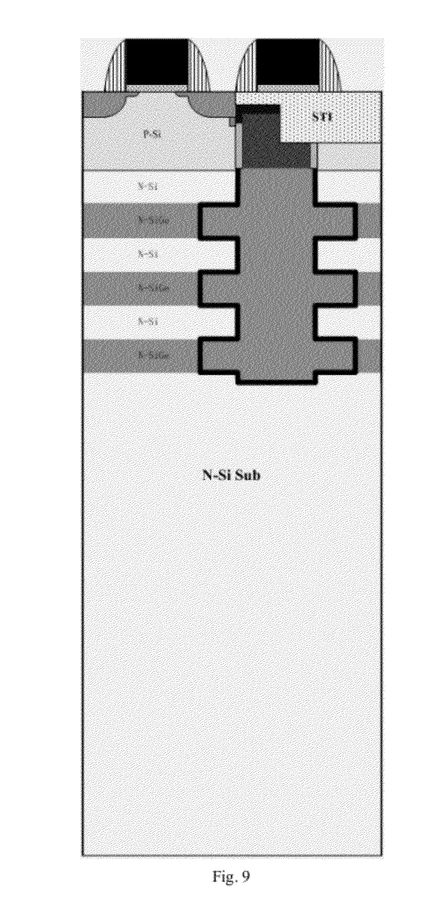

Referring to FIG. 9, the difference between this embodiment and the first one is that the top layer of the multilayer structure is N-type Si layer and a P-type Si layer is formed on the top N-type Si layer in this embodiment.

It should be noticed that there is no limitations for the order or the number of layers for alternatively arranged N-type SiGe layers and N-type Si layer in the present invention.

The above description of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A DRAM cell structure with extended trench, comprising a NMOS transistor and a trench capacitor connected with the source electrode of the NMOS transistor; wherein the trench capacitor comprises:
a semiconductor substrate;
a multilayer structure as the bottom plate of the trench capacitor, formed on the semiconductor substrate, which is composed of N-type SiGe layers and N-type Si layers arranged alternatively;
a trench formed through the multilayer structure and deep to the semiconductor substrate, whose sidewall cross section is serrate-shaped;
a dielectric layer formed on the inner face of the trench;
a first polycrystalline silicon layer filled in the trench as the top plate of the trench capacitor; and
a P-type Si layer formed on the multilayer structure;
wherein the NMOS transistor fabricated on the P-type Si layer.

2. The DRAM cell structure with extended trench in claim 1, wherein the sidewall of the trench is sunken in each N-type SiGe layer.

3. The DRAM cell structure with extended trench in claim 1, wherein the thickness of each N-type SiGe layer is more than 30 nm and the thickness of each N-type Si layer is more than 30 nm.

4. The DRAM cell structure with extended trench in claim 1, wherein the thickness of the P-type layer is more than 100 nm.

5. The DRAM cell structure with extended trench in claim 1, wherein a second polycrystalline silicon layer contact to the first polycrystalline silicon layer is formed in the P-type Si layer of the trench capacitor; a collar oxide layer is fabricated on the sidewall of the second polycrystalline silicon layer; a buried strap which is connected with the source electrode of the NMOS transistor through an ion implanted region is fabricated on the top of one side of the second polycrystalline silicon layer; and a shallow trench isolation structure is fabricated on the top of the other side of the second polycrystalline silicon layer.

6. A method of manufacturing of a DRAM cell structure with extended trench, the method comprises:
(a) creating a multilayer structure on a semiconductor substrate by forming alternative N-type SiGe layers and N-type Si layers adopting doping and epitaxial growth process and then forming a P-type Si layer on the multilayer structure;
(b) forming a oxide covering layer on the P-type Si layer and then forming a nitride covering layer on the oxide covering layer;
(c) defining etching window adopting photolithographic and etch process and then proceeding trench etching until the semiconductor substrate is exposed;
(d) removing parts of the N-type SiGe layers next to the sidewall of the trench adopting selective etching process in order to form a serrate-shaped sidewall cross section;
(e) forming a dielectric layer on the inner face of the trench;
(f) filling polycrystalline silicon material in the trench to form a first polycrystalline layer and removing redundant polycrystalline material in the surface adopting chemical mechanical planarization process;
(g) fabricating a NMOS transistor on the P-type Si layer and forming an electric connection between the source electrode of the NMOS transistor and the first polycrystalline layer.

7. The method of manufacturing of a DRAM cell structure with extended trench of claim 6, wherein step (c) comprises steps: forming a hard mask layer on the nitride covering layer and then forming a photoresist layer on the hard mask layer; creating etching window of the trench on the photoresist layer adopting photolithographic process; transferring the etching window of the trench defined to the hard mask layer; removing the photoresist layer; proceeding trench etching down to the semiconductor substrate; and removing the hard mask.

8. The method of manufacturing of a DRAM cell structure with extended trench MOS device of claim 6, wherein in step (d), the depth of the part etched by selective etching process of the N-type SiGe layer is smaller than the length of corresponding NMOS transistor channel.

9. The method of manufacturing of a DRAM cell structure with extended trench MOS device of claim 6, wherein step (g) comprises steps: etching the first polycrystalline layer to remove that part of the first polycrystalline located in the P-type Si layer; depositing a SiO₂ film which is then etched to form a collar oxide layer on the side wall, and then implanting polycrystalline material to form a second polycrystalline layer which is connected with the first polycrystalline layer; creating a buried strap on the second polycrystalline and connecting the buried strap with the source electrode of NMOS transistor.

10. The method of manufacturing of a DRAM cell structure with extended trench MOS device of claim 9, wherein an ion implantation region is created between the buried strap and the source electrode of NMOS transistor.
